(19) United States
(12) Patent Application Publication
(10) Pub. No.: US 2008/0175411 A1
(43) Pub. Date: Jul. 24, 2008

(54) PLAYER DEVICE WITH AUTOMATIC SETTINGS

(76) Inventor: Jens GREVE, Stockholm (SE)

Correspondence Address: WARREN A. SKLAR (SOER);RENNER, OTTO, BOISSELLE & SKLAR, LLP, 1621 EUCLID AVENUE, 19TH FLOOR, CLEVELAND, OH, 44115, US

(21) Appl. No.: 11/624,760

(22) Filed: Jan. 19, 2007

(51) Int. Cl. H03G 5/00

(52) U.S. Cl. 381/103

(57) ABSTRACT

The invention relates to a multimedia player device for playing multimedia with automatic sound and video settings, and particularly a player device for playing sound from a data file, capable of automatic equalizer setting based on meta-data contained in the data file. The player device (1) comprises: a decoder (3) for extracting meta-data from a data file (2) further containing sound data; a control unit (4); a sound reproduction system (5) with an equalizer (6), adapted to reproduce sound from the sound data; wherein the control unit (4) is adapted to control the equalizer (6) with regard to tone control in dependence of the meta-data, suitably genre information. A number of predefined equalizer settings may be used automatically by the device.

### FIELD OF THE INVENTION

The present invention relates to a multimedia player device for playing multimedia with automatic sound and video settings, and particularly a player device for playing sound from a data file, capable of automatic equalizer setting based on meta-data contained in the data file. A number of predefined equalizer settings may be used automatically by the device.

### BACKGROUND OF THE INVENTION

Today there exist an abundance of sound systems and music players capable of reproducing sound stored as binary data files on various media, such as CD, hard disks, flash memories etc. The data may be stored in various formats, such as MP3, WMA, AAC or Ogg Vorbis. As a rule, a player contains an equalizer for tone control, i.e. adapting boost or attenuation of frequency bands to current speakers used or the user's preference in dependence of type of music. Predefined settings may be provided and the user may make manual adjustments at any time.

The sound data files may contain meta-data, i.e. data besides the sound data. A special format for meta-data is ID3 tags. The meta-data may describe the content of the file, including song title, artist, album, year, comment, track and genre. The tags are used for searching as well as displaying the title being played.

The experience and acoustic presentation of different sound files may benefit from different equalizer settings. For example audio books should be optimized for speech or vocal settings, and pop music should be optimized to give a boost to the bass and the treble. Today, sound systems may be provided with predefined equalizer curves to be selected by the user or default settings. Also, the user may of course change the settings manually. In the ID3 format there is also a dedicated frame that may be used for defining equalizer settings.

### SUMMARY OF THE INVENTION

An object of the present invention is to provide a player device with automatic equalizer setting depending on meta-data, particularly genre. The idea is to use the meta-data to automatically associate a specific sound data file with a predefined equalizer setting that matches the specific sound file, e.g. use POP settings for pop music and VOICE setting for an audio book.

A further object of the present invention is to provide a multimedia player device for playing multimedia with automatic sound and video settings depending on meta-data.

In one aspect the invention provides a player device comprising:

a decoder for extracting meta-data from a data file further containing sound data;
a control unit;
a sound reproduction system with an equalizer, adapted to reproduce sound from the sound data;
a user interface, wherein the control unit is adapted to control the equalizer with regard to tone control in dependence of the meta-data.

Suitably, the decoder is adapted to extract genre information from the meta-data, and the control unit is adapted to control the equalizer in dependence of the genre information.

Suitably, the control unit is adapted to store genre information, such that genres are associated in an arrangement with a number of predefined equalizer settings.

Preferably, the arrangement with the number of predefined equalizer settings is adjustable through the user interface.

Suitably, the number of predefined equalizer settings is adjustable.

Suitably, the association between a specific genre and a specific equalizer setting is adjustable.

In one embodiment, the control unit is adapted to adjust and store a predefined equalizer setting associated with a genre currently used with a data file, if an adjustment is made through the user interface.

In a further embodiment, if the specific genre belonging to a group is used for the first time and if the user adjusts the equalizer setting, the control unit is adapted to remove the genre from the group and to form a new predefined equalizer setting associated with the specific genre.

The player device may further comprise a communication interface, wherein the control unit is adapted to establish a connection through the communication interface to a database for gathering meta-data, if the data file is lacking meta-data.

The player device may be a computer, a music player, a mobile telephone, a pager, a communicator, a smart phone, or an electronic organiser.

In a second aspect the invention provides a player device comprising: a decoder for extracting meta-data from a data file further containing multimedia data;

a control unit;
a reproduction system with controllable presentation means, adapted to present multimedia from the multimedia data;
a user interface, wherein the control unit is adapted to control the presentation means with regard to sound settings and/or video settings in dependence of the meta-data.

### BRIEF DESCRIPTION OF THE DRAWINGS

The invention will be described in detail below with reference to the accompanying drawings, in which:

FIG. 1 is a schematic diagram of a player according to an embodiment of the invention.

### DETAILED DESCRIPTION OF PREFERRED EMBODIMENTS

The invention will be described with reference to a portable music player device, such as a dedicated music player, a mobile telephone, a pager, a communicator, a smart phone or an electronic organizer. The invention is equally applicable in general multimedia players and stationary devices, such as video systems, sound systems and stationary computers.

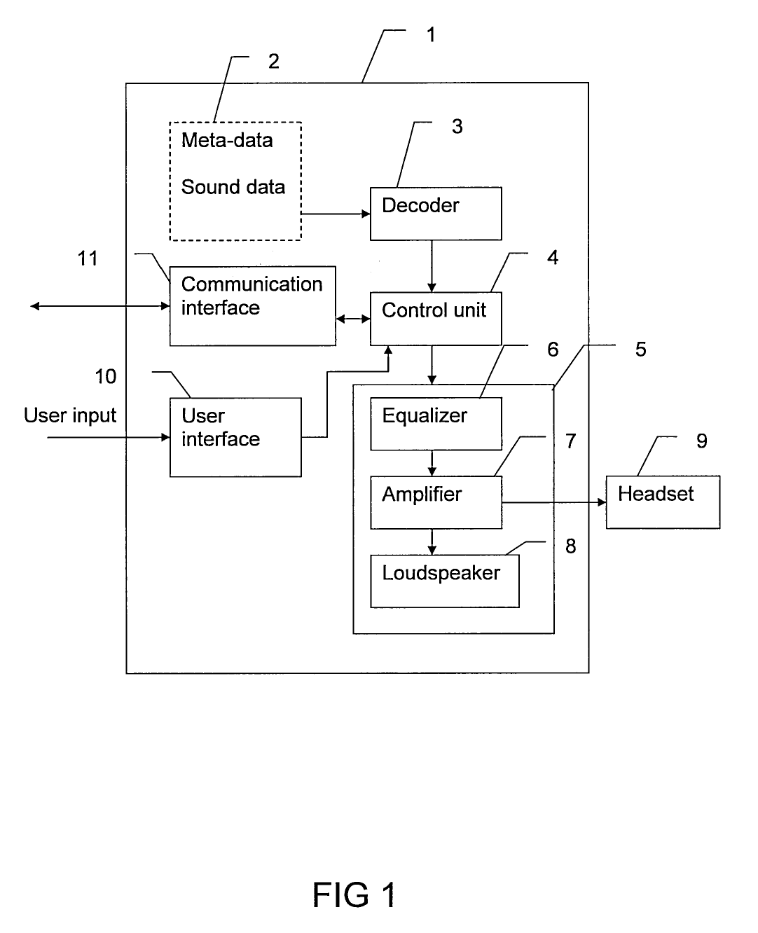

A schematic illustration of an embodiment of a music player according to the invention is shown in FIG. 1. The player device 1 is capable of playing sound from a data file 2. Generally, the file may be a “multimedia” file that contains graphics, animation, audio or video. The data file 2 may reside in a memory incorporated in or connected to the device 1, or be streamed down via a communication interface 11 and partially stored in a buffer memory. As is mentioned previously, various formats for sound data exist today. They comprise meta-data and sound data. The meta-data may reside as a header or at the end of the data file. In case of the ID3 format, the ID3 tag comprises e.g. a text field, a date field and a genre field, which contains a predefined category code from 0 to 79. It has further been extended by 46 Winamp extensions. They include various genres such as popular music, jazz, classical, opera, acoustic, speech etc.

The player device 1 comprises a decoder 3 for extracting the meta-data and forwarding sound data to a sound reproduction system 5 through a control unit 4 controlling the operation of the device by means of hardware and software. The sound reproduction system 5 comprises an equalizer 6, a least one amplifier 7, as necessary, and possibly an internal loudspeaker 8. The device 1 may also be connected to an external loudspeaker or a headset 9. A user interface 10 with control buttons, a keypad or other knobs, is provided for letting the user input commands for volume control, track selection and manual equalizer settings etc.

As is known, the equalizer is provided for tone control, i.e. adjusting boost and/or attenuation of bass and treble. In portable devices the equalizer often comprises five frequency bands ranging from lowest bass to highest treble, but other numbers of bands are also possible within the scope of the invention.

As mentioned above, different equalizer settings are suitable for different genres. In one embodiment five equalizer settings are predefined as groups in the control unit. Each of the genres is associated with one of the five predefined settings. For example, pop/rock/disco and similar genres have enhanced bass and treble response, jazz/classical and similar genres have a flat response, acoustic music has enhanced treble response, techno music has even further enhanced bass (megabass) and treble response, and speech has enhanced middle register but attenuated bass.

Suitably, the associations between genre and equalizer setting are stored in a look-up table. If a data file 2 is lacking genre information, a default setting may be used, e.g. one of the five predefined settings. Also, genres may be associated with a preset volume level.

In one embodiment, the user may adjust the predefined arrangement of the settings through the user interface 10, to take into account his own taste, the current loudspeaker or headset system used, room acoustics etc. The new settings are stored and used the next time for the same genre group, until the user makes a new adjustment.

In a further embodiment, the user may add further predefined settings and change the associations between genre and predefined settings.

In a still further embodiment, whenever the user adjusts an equalizer setting for a group to which the genre belongs, the predefined setting is automatically adjusted and stored.

In a yet further embodiment, if a specific genre belonging to a group is used for the first time and if the user adjusts the equalizer setting, the genre is removed from the group and a new predefined setting is formed for the genre in question. Next time the user wants to listen to a sound file associated with this genre, this new predefined setting is used automatically.

In one embodiment, the device 1 is provided an override button or function, letting the user switch-off the automatic equalizer setting adjustment and instead use a default setting.

As is known, the user may edit the meta-data, e.g. using an ID3 tagger, to fill in or edit genre and other information.

In one embodiment, if the meta-data is lacking, the player device 1 is adapted to establish a connection to a database to gather meta-data. In this case, the device 1 is a player device comprising a communication interface 11, as often provided in mobile telephones and computers. There exist today databases capable of identifying songs from a part of sound data and sending back information about the song to the requesting device.

In a further embodiment of the invention, the player is capable if presenting multimedia files, in other words containing sound and images (video). The player comprises a reproduction system with presentation means, generally comprising a display screen and loudspeakers. Then the meta-data may contain information relating to sound settings and/or video settings. Similarly to above, the player is capable of reading meta-data in multimedia files and of using it to adjust the presentation means automatically with regard to sound settings (equalizer settings and surround sound settings etc) and/or video settings (picture settings, such as color, brilliance, contrast, widescreen aspect ratio etc.)

The invention may be implemented by means of suitable combinations of hardware and software. The invention is not limited to any particular format of multimedia data and meta-data, though the examples cited above are suitable. Further formats may be developed in the future providing the same technical functions. The scope of the invention is only limited by the claims below.

1. A player device comprising:
a decoder for extracting meta-data from a data file further containing sound data;
a control unit;
a sound reproduction system with an equalizer, adapted to reproduce sound from the sound data;
a user interface, wherein the control unit is adapted to control the equalizer with regard to tone control in dependence of the meta-data.

2. A player device in accordance with claim 1, wherein the decoder is adapted to extract genre information from the meta-data, and the control unit is adapted to control the equalizer in dependence of the genre information.

3. A player device in accordance with claim 2, wherein the control unit is adapted to store genre information, such that genres are associated in an arrangement with a number of predefined equalizer settings.

4. A player device in accordance with claim 3, wherein the arrangement with the number of predefined equalizer settings is adjustable through the user interface.

5. A player device in accordance with claim 4, wherein the number of predefined equalizer settings is adjustable.

6. A player device in accordance with claim 4, wherein the association between a specific genre and a specific equalizer setting is adjustable.

7. A player device in accordance with claim 2, wherein the control unit is adapted to adjust and store a predefined equalizer setting associated with a genre currently used with a data file, if an adjustment is made through the user interface.

8. A player device in accordance with claim 2, wherein, if the specific genre belonging to a group is used for the first time and if the user adjusts the equalizer setting, the control unit is adapted to remove the genre from the group and to form a new predefined equalizer setting associated with the specific genre.

9. A player device in accordance with claim 1, further comprising a communication interface, wherein the control unit is adapted to establish a connection through the communication interface to a database for gathering meta-data, if the data file is lacking meta-data.

10. A player device in accordance with claim 1, wherein the device is a computer, a music player, a mobile telephone, a pager, a communicator, a smart phone, or an electronic organiser.

11. A player device comprising:
a decoder for extracting meta-data from a data file further containing multimedia data;
a control unit;
a reproduction system with controllable presentation means, adapted to present multimedia from the multimedia data;
a user interface, wherein the control unit is adapted to control the presentation means with regard to sound settings and/or video settings in dependence of the meta-data.
